(19) United States
(12) Patent Application Publication
(10) Pub. No.: US 2026/0211037 A1
(43) Pub. Date: Jul. 23, 2026

(54) DETECTION DEVICE AND DETECTION METHOD FOR CHARGING PILE

(71) Applicant: WISTRON CORPORATION, New Taipei City (TW)

(72) Inventors: Tsung Han YU, New Taipei City (TW); Wen Ju CHEN, New Taipei City (TW)

(73) Assignee: WISTRON CORPORATION, New Taipei City (TW)

(21) Appl. No.: 19/170,282

(22) Filed: Apr. 4, 2025

(30) Foreign Application Priority Data
Jan. 23, 2025 (TW) 114103057

(51) Int. Cl. G01R 31/327; B60L 53/60; G08B 21/18

(52) U.S. Cl. CPC G01R 31/3278; B60L 53/60; G08B 21/185

(57) ABSTRACT

A detection device and a detection method for a charging pile are provided. The charging pile includes a first power line, a second power line, a first output terminal, a second output terminal, and a relay. The second output terminal is connected to the second power line. The relay is connected between the first power line and the first output terminal. The detection device includes a virtual load circuit, a detection circuit, and a controller. The controller turns on the relay and controls the virtual load circuit to form a virtual load path, controls the detection circuit to generate a test current, and begins timing form the generation of the test current. The controller turns off the relay in response to the test current, ends timing to generate a timing value, and determines the aging condition of the relay according to the timing value.

### CROSS-REFERENCE TO RELATED APPLICATIONS

This application claims the priority and benefit of Taiwan Patent Application No. 114103057, filed on January 23, 2025, the disclosure of which is hereby incorporated in its entirety by reference herein.

### TECHNICAL FIELD

The disclosure relates to a detection device and a detection method, and particularly relates to a detection device and a detection method for a charging pile.

### BACKGROUND

### Related Art

Generally, a charging pile includes several power lines, several output terminals, and a relay. One of the output terminals is connected to one of the power lines. The relay is connected between the other one of the power lines and the other one of the output terminals. The output terminals are connected to a charging gun. In response to an abnormal condition of the charging pile, such as a leakage current from the one of the power lines, the charging pile turns off the relay. Therefore, the tripping of the relay interrupts the leakage current from the one of the power lines, thereby reducing the risk of electrical shock to users. However, over time, the relay gradually ages.

### SUMMARY

The disclosure provides a detection device and a detection method for a charging pile, which can inspect the relay of the charging pile.

In one embodiment of the disclosure, the detection device is applicable to a charging pile. The charging pile includes a first power line, a second power line, a first output terminal, a second output terminal, and a relay. The second output terminal is connected to the second power line. A first terminal of the relay is connected to the first power line. A second terminal of the relay is connected to the first output terminal. The detection device includes a virtual load circuit, a detection circuit, and a controller. The virtual load circuit is connected between the second output terminal and the second terminal of the relay. The detection circuit is connected to the first power line and the second power line. The controller is connected to the relay, the virtual load circuit, and the detection circuit. The controller turns on the relay and controls the virtual load circuit to form a virtual load path between the second output terminal and the second terminal of the relay, controls the detection circuit to generate a test current between the first power line and the second power line, and begins timing from the generation of the test current. The controller turns off the relay in response to the test current to stop the generation of the test current, ends timing to generate a timing value, and determines the aging condition of the relay according to the timing value.

In another embodiment of the disclosure, the detection method is applicable to a charging pile. The charging pile includes a first power line, a second power line, a first output terminal, a second output terminal, and a relay. The second output terminal is connected to the second power line. A first terminal of the relay is connected to the first power line. A second terminal of the relay is connected to the first output terminal. The detection method includes the following. A virtual load circuit and a detection circuit are provided, in which the virtual load circuit is connected between the second output terminal and the second terminal of the relay, and the detection circuit is connected to the first power line and the second power line. The relay is turned on and the virtual load circuit is controlled to form a virtual load path between the second output terminal and the second terminal of the relay. The detection circuit is controlled to generate a test current between the first power line and the second power line, and timing begins from the generation of the test current. The relay is turned off in response to the test current to stop the generation of the test current, and timing is ended to generate a timing value. Also, the aging condition of the relay is determined according to the timing value.

### BRIEF DESCRIPTION OF THE DRAWINGS

FIG. 1 is a schematic diagram illustrating a charging pile and a detection device according to an embodiment of the disclosure.

FIG. 2 is a flowchart illustrating a detection method according to an embodiment of the disclosure.

FIG. 3 is a schematic diagram illustrating the charging pile and the detection device according to an embodiment of the disclosure.

FIG. 4 is a schematic diagram illustrating a programmable resistor circuit and a test switch according to an embodiment of the disclosure.

FIG. 5 is a flowchart illustrating the detection method according to an embodiment of the disclosure.

### DETAILED DESCRIPTION

Some embodiments of the disclosure will now be described in detail with reference to the accompanying drawings. In the following description, when the same reference signs appear in different drawings, the same reference signs will be regarded as the same or similar components. These embodiments are merely a part of the disclosure and do not disclose all possible implementations of the disclosure. More precisely, these embodiments are merely examples within the scope of the appended claims of the disclosure.

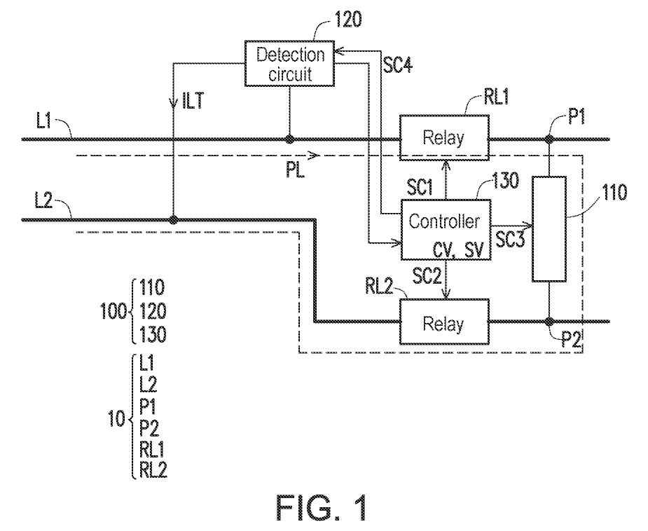

Please refer to FIG. 1, which is a schematic diagram illustrating a charging pile and a detection device according to an embodiment of the disclosure. In one embodiment, a detection device 100 is applicable to a charging pile 10. The charging pile 10 includes a first power line L1, a second power line L2, a first output terminal P1, a second output terminal P2, and relays RL1, RL2. The first power line L1 and the second power line L2 are used to transmit power. The first output terminal P1 and the second output terminal P2 are connected to a charging gun (not shown). The second output terminal P2 is connected to the second power line L2. The first terminal of the relay RL1 is connected to the first power line L1. The second terminal of the relay RL1 is connected to the first output terminal P1. The first terminal of the relay RL2 is connected to the second power line L2. The second terminal of the relay RL2 is connected to the second output terminal P2.

In one embodiment, the detection device 100 includes a virtual load circuit 110, a detection circuit 120, and a controller 130. The virtual load circuit 110 is connected between the first output terminal P1 and the second output terminal P2. In other words, the virtual load circuit 110 is connected between the second terminal of the relay RL1 and the second terminal of the relay RL2. The detection circuit 120 is connected to the first power line L1 and the second power line L2.

In one embodiment, the controller 130 is connected to the relays RL1, RL2, the virtual load circuit 110, and the detection circuit 120. The controller 130 turns on the relays RL1, RL2 and controls the virtual load circuit 110 to form a virtual load path PL between the first output terminal P1 (that is, at the second terminal of the relay RL1) and the second output terminal P2 (that is, at the second terminal of the relay RL2). The controller 130 also controls the detection circuit 120 to generate a test current ILT between the first power line L1 and the second power line L2. In addition, the controller 130 further begins timing from the generation of the test current ILT. The controller 130, in response to the test current ILT, turns off the relays RL1, RL2 to stop the generation of the test current ILT, and ends timing to generate a timing value CV.

In one embodiment, the test current ILT between the first power line L1 and the second power line L2 may simulate a leakage current occurring on either the first power line L1 or the second power line L2.

In one embodiment, in response to the relays RL1, RL2 completing tripping (that is, being turned off), the virtual load path PL is turned off. The timing value CV is generated. In other words, the timing value CV may reflect the time required for the relays RL1, RL2 to complete tripping when the test current ILT is generated. Subsequently, the controller 130 may determine the aging condition of the relays RL1, RL2 according to the timing value CV.

It is worth mentioning here that the detection device 100 generates the timing value CV based on the generation of the test current ILT. The timing value CV is related to the time required for the relays RL1, RL2 to complete tripping when the test current ILT is generated. In this way, the detection device 100 may determine the aging condition of the relays RL1, RL2 according to the timing value CV.

In one embodiment, the controller 130 may control the relay RL1 using a control signal SC1. The controller 130 may control the relay RL2 using a control signal SC2. The controller 130 may control the virtual load circuit 110 using a control signal SC3. The controller 130 may control the detection circuit 120 to provide the test current ILT using a control signal SC4.

In one embodiment, "aging" is a state where components in the relays RL1, RL2 deteriorate, causing a delay in the tripping of the relays RL1, RL2. The controller 130 determines whether at least one of the relays RL1, RL2 is aging according to the comparison result between the timing value CV and a set value SV. In response to the timing value CV being greater than the set value SV, the controller 130 determines the aging condition of both of the relays RL1, RL2. In response to the timing value CV being less than or equal to the set value SV, the controller 130 determines that one of the relays RL1, RL2 is, or both the relays RL1, RL2 are not aged yet. Aforementioned set value SV refers to, for example, the Interrupting Time under UL2231of Underwriters Laboratories.

In some embodiments, the controller 130 may turn off one of the relays RL1, RL2 in response to the test current ILT to stop the generation of the test current ILT. For example, the controller 130 turns off the relay RL1 in response to the test current ILT. Therefore, the timing value CV is related to the time required for the relay RL1 to complete tripping when the test current ILT is generated. The detection device 100 may determine the aging condition of the relay RL1. In another example, the controller 130 turns off the relay RL2 in response to the test current ILT. Therefore, the timing value CV is related to the time required for the relay RL2 to complete tripping when the test current ILT is generated. The detection device 100 may determine the aging condition of the relay RL2.

In one embodiment, the relays RL1, RL2 may be implemented by electromagnetic relays, solid-state relays, thermal relays, or photosensitive relays, respectively. The controller 130 may be, for example, a Central Processing Unit (CPU), or other programmable general-purpose or special-purpose microprocessors, a Digital Signal Processor (DSP), a programmable controller, an Application Specific Integrated Circuit (ASIC), a Programmable Logic Device (PLD), or other similar devices or combinations of these devices.

In some embodiments, the charging pile 10 may not include the relay RL2 (Not shown in FIGS.). Therefore, the virtual load circuit 110 is connected between the second terminal of the relay RL1 and the second output terminal P2. The controller 130 turns off the relay RL1 in response to the test current ILT. Thus, the timing value CV is related to the time required for the relay RL1 to complete tripping when the test current ILT is generated. In response to the timing value CV being greater than the set value SV, the controller 130 determines the aging condition of the relays RL1. In response to the timing value CV being less than or equal to the set value SV, the controller 130 determines that the relays RL1 is not aged yet. In some embodiments, the charging pile 10 may not include the relay RL1 (Not shown in FIGS). Therefore, the virtual load circuit 110 is connected between the second terminal of the relay RL2 and the first output terminal P1. The controller 130 turns off the relay RL2 in response to the test current ILT. Thus, the timing value CV is related to the time required for the relay RL2 to complete tripping when the test current ILT is generated. In response to the timing value CV being greater than the set value SV, the controller 130 determines the aging condition of the relays RL2. In response to the timing value CV being less than or equal to the set value SV, the controller 130 determines that the relays RL2 is not aged yet.

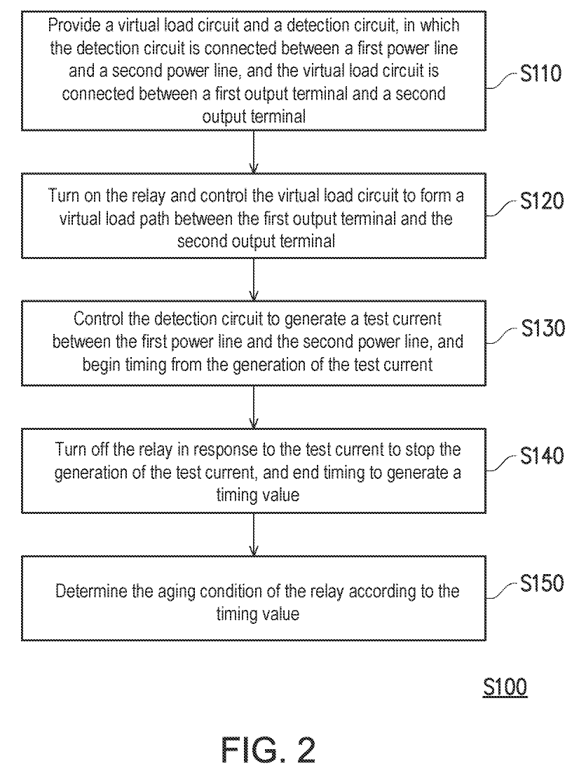

Please refer to FIG. 1 and FIG. 2. FIG. 2 is a flowchart illustrating a detection method according to an embodiment of the disclosure. In one embodiment, a detection method S110 is applicable to the charging pile 10. The detection method S100 is applicable for detecting the relays RL1, RL2 of the charging pile 10. The detection method S100 includes Steps S110 to S150. In Step S110, the virtual load circuit 110 and the detection circuit 120 are provided. The virtual load circuit 110 is connected between the first output terminal P1 (that is, at the second terminal of the relay RL1) and the second output terminal P2 (that is, at the second terminal of the relay RL2). In other words, the virtual load circuit 110 is connected between the second terminal of the relay RL1 and the second terminal of the relay RL2. The detection circuit 120 is connected to the first power line L1 and the second power line L2.

In Step S120, the controller 130 turns on the relays RL1, RL2 and controls the virtual load circuit 110 to form the virtual load path PL between the first output terminal P1 and the second output terminal P2. In Step S130, the controller 130 controls the detection circuit 120 to generate the test current ILT between the first power line L1 and the second power line L2, and begins timing from the generation of the test current ILT. In Step S140, the controller 130 turns off the relays RL1, RL2 in response to the test current ILT to stop the generation of the test current ILT, and ends timing to generate the timing value CV. In Step S150, the controller 130 determines the aging condition of the relays RL1, RL2 according to the timing value CV.

In some embodiments, in Step S140, the controller 130 turns off the relay RL1 to stop the generation of the test current ILT, and ends timing to generate the timing value CV. In Step S150, the controller 130 determines the aging condition of the relay RL1 according to the timing value CV. In some embodiments, in Step S140, the controller 130 turns off the relay RL2 to stop the generation of the test current ILT, and ends timing to generate the timing value CV. In Step S150, the controller 130 determines the aging condition of the relay RL2 according to the timing value CV.

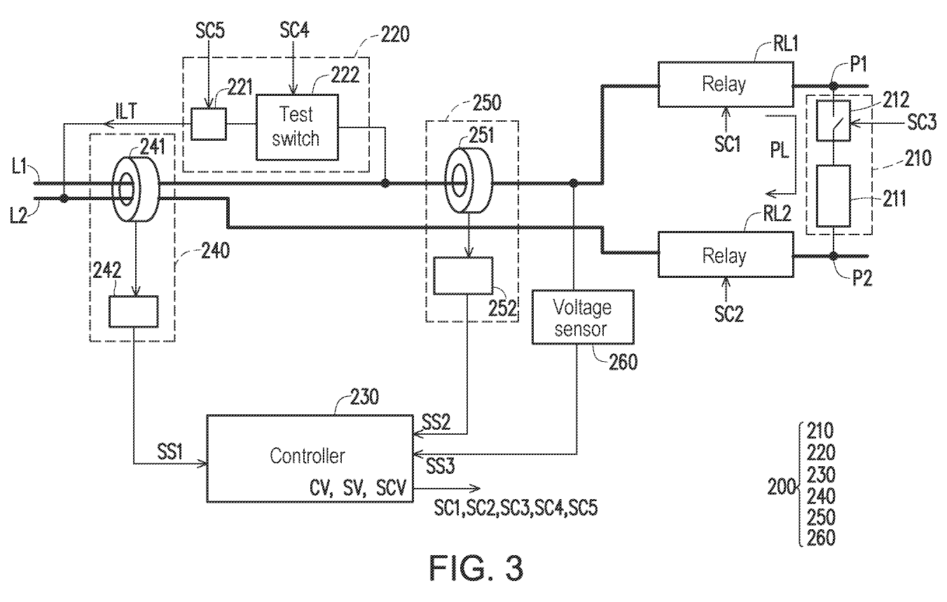

Please refer to FIG. 3. FIG. 3 is a schematic diagram illustrating the charging pile and the detection device according to an embodiment of the disclosure. In one embodiment, a detection device 200 is applicable to the charging pile 10. The detection device 200 includes a virtual load circuit 210, a detection circuit 220, a controller 230, and current detectors 240, 250. The virtual load circuit 210 includes a virtual load 211 and a load switch 212. The load switch 212 is connected in series with the virtual load 211 between the first output terminal P1 (that is, at the second terminal of the relay RL1) and the second output terminal P2 (that is, at the second terminal of the relay RL2). In one embodiment, the first terminal of the load switch 212 is connected to the first output terminal P1. The virtual load 211 is connected between the second terminal of the load switch 212 and the second output terminal P2. The virtual load 211 may be, for example, a resistor serving as a load, but the disclosure is not limited thereto. The controller 230 is connected to the control terminal of the load switch 212. The controller 230 turns on the relays RL1, RL2 and the load switch 212 to form the virtual load path PL.

In one embodiment, the current detector 240 is connected to the controller 230. The current detector 240 generates a current detection signal SS1 in response to the test current ILT. The controller 230 receives the current detection signal SS1 from the current detector 240. The controller 230 times the generation of the test current ILT according to the current detection signal SS1, and provides the control signals SC1, SC2. The relay RL1 is turned off according to the control signal SC1. The relay RL2 is turned off according to the control signal SC2.

The current detector 250 is connected to the controller 230. The current detector 250 senses the test current ILT flowing through one of the first power line L1 and the second power line L2 to generate a sensor signal SS2, and provides the sensor signal SS2 to the controller 230. In response to the sensor signal SS2 indicating that the current value of the test current ILT is equal to zero amperes, the controller 230 stops timing according to the sensor signal SS2 to generate the timing value CV.

In one embodiment, the current detector 240 includes a current coupling component 241 and a detecting circuit 242. The current coupling component 241 may, for example, detect the current in the first power line L1 and the second power line L2 to generate a coupled current. The current value of the coupled current is positively correlated with the current value of the test current ILT. The detecting circuit 242 is connected to the current coupling component 241. The detecting circuit 242 generates the current detection signal SS1 according to the coupled current.

In one embodiment, the current detector 250 includes a current coupling component 251 and a detecting circuit 252. The current coupling component 251 may, for example, detect the current in the first power line L1 to generate a coupled current. The current value of the coupled current is positively correlated with the current value of the test current ILT. The detecting circuit 252 is connected to the current coupling component 251. The detecting circuit 252 generates the sensor signal SS2 according to the coupled current.

In one embodiment, the detection circuit 220 includes a programmable resistor circuit 221 and a test switch 222. The test switch 222 is connected in series with the programmable resistor circuit 221 between the first power line L1 and the second power line L2. During the period in which the virtual load path PL is provided, the controller 230 turns on the test switch 222 and adjusts the resistance value of the programmable resistor circuit 221 to make the current value of the test current ILT reach a set current value SCV. In one embodiment, the controller 230 may use the control signal SC4 to turn on the test switch 222, and use a control signal SC5 to set the resistance value of the programmable resistor circuit 221.

In one embodiment, the detection device 200 further includes a voltage sensor 260. The voltage sensor 260 senses the voltage value on the first power line L1 to generate a voltage detection signal SS3. The controller 230 adjusts the resistance value of the programmable resistor circuit 221 according to the voltage detection signal SS3 and the set current value SCV to make the current value of the test current ILT reach the set current value SCV. Therefore, the controller 230 may maintain the current value of the test current ILT at the set current value SCV according to the voltage detection signal SS3.

For example, the voltage difference between the first power line L1 and the second power line L2 is approximately 120 volts. The lowest human body impedance is approximately 500 ohms (?). The set current value SCV is approximately equal to 264 milliamperes (that is, SCV = 120 × 1.1 ÷ 500). Based on the test specifications of the relays RL1 and RL2, the set value SV is, for example, 25 milliseconds. In other words, according to the test current ILT of 264 milliamperes, the relays RL1 and RL2 must complete tripping within 25 milliseconds after the test current ILT is generated. If tripping is completed within 25 milliseconds after the test current ILT is generated, then this indicates that the test of the relays RL1 and RL2 are qualified. If tripping is completed beyond 25 milliseconds after the test current ILT is generated, then this indicates that both of the relays RL1 and RL2 are not qualified in the test.

In one embodiment, the load switch 212 and the test switch 222 are respectively implemented by any type of relay or at least one transistor switch.

The detection device 200 may also execute the detection method S100.

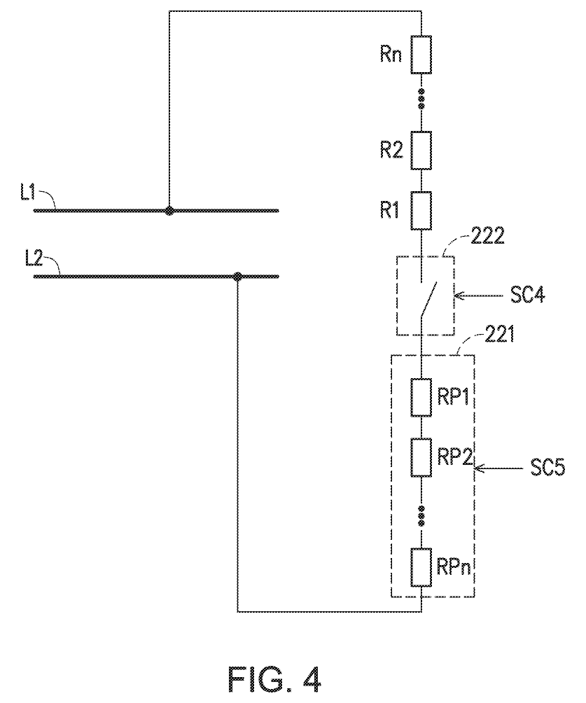

Please refer to FIG. 4. FIG. 4 is a schematic diagram of a programmable resistor circuit and a test switch according to an embodiment of the disclosure. In one embodiment, the first terminal of the test switch 222 is connected to the first power line L1 through resistors R1 to Rn, for example. The programmable resistor circuit 221 is connected between the second terminal of the test switch 222 and the second power line L2. The programmable resistor circuit 221 includes programmable resistors RP1 to RPn. The programmable resistors RP1 to RPn are connected in series with each other. The controller 230 may control the resistance value of at least one of the programmable resistors RP1 to RPn. For example, the controller 230 provides the control signal SC5 to the programmable resistor circuit 221 through an I2C interface to adjust the resistance value of at least one of the programmable resistors RP1 to RPn using the control signal SC5.

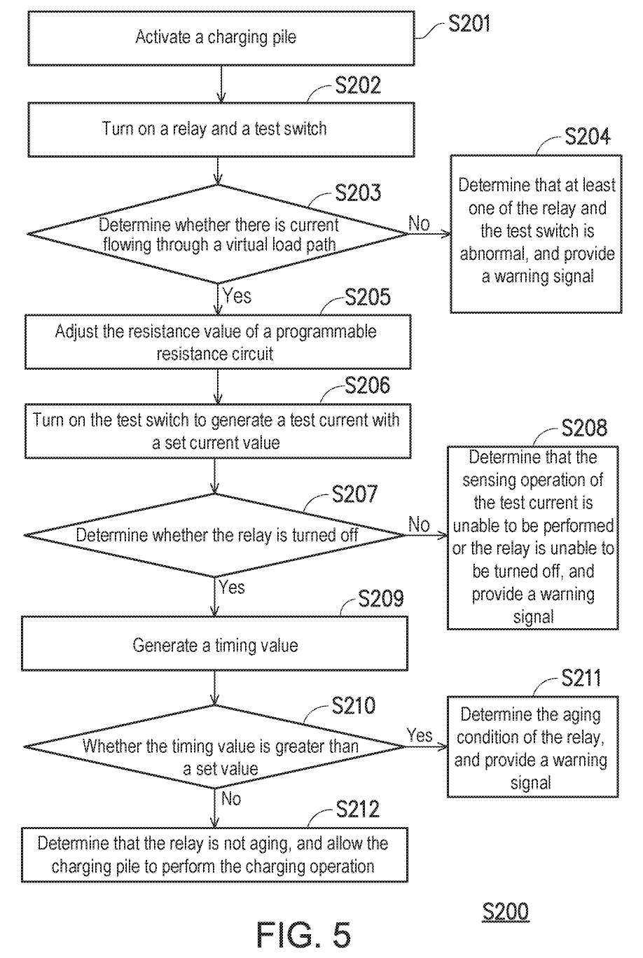

Please refer to FIG. 2 and FIG. 5. FIG. 5 is a flowchart illustrating the detection method according to an embodiment of the disclosure. In one embodiment, a detection method S200 is applicable for detecting the relays RL1, RL2 of the charging pile 10. The detection method S200 includes Steps S201 to S212. In Step S201, the charging pile 10 is activated. Therefore, the first power line L1 and the second power line L2 receive power. In Step S202, the controller 230 turns on the relays RL1, RL2 and the test switch 222. In Step S203, the controller 230 determines whether there is current flowing through the virtual load path PL. In response to no current flowing through the virtual load path PL, the controller 230 determines that at least one of the relays RL1, RL2 and the test switch 222 is not properly turned on, thereby preventing the virtual load path PL from transmitting power. Therefore, in Step S204, the controller 230 determines that at least one of the relays RL1, RL2 and the test switch 222 is abnormal and provides a warning signal. On the other hand, in response to current flowing through the virtual load path PL, the controller 230 adjusts the resistance value of the programmable resistor circuit 221 in Step S205. In one embodiment, the controller 230 may detect the voltage value of the power source through the first power line L1, and obtain a target resistance value according to the voltage value of the power source and the set current value SCV. The controller 230 adjusts the resistance value of the programmable resistor circuit 221 according to the target resistance value.

In one embodiment, the controller 230 subtracts the sum of the resistance values of the resistors R1 to Rn from the target resistance value to generate the aforementioned resistance difference, and adjusts the resistance value of the programmable resistor circuit 221 to the aforementioned resistance difference.

Taking FIG. 4 as an example, the controller 230 subtracts the sum of the resistance values of the resistors R1 to Rn and the virtual load 211 from the target resistance value to generate the aforementioned resistance difference, and adjusts the resistance value of the programmable resistor circuit 221 to the aforementioned resistance difference.

In Step S206, the controller 230 turns on the test switch 222. Therefore, a test current ILT with the set current value SCV is generated. The current detector 240 starts to sense the test current ILT.

In Step S207, the controller 230 determines whether the relays RL1, RL2 are turned off (tripped). In response to the relays RL1, RL2 not being turned off, the controller 230 determines in Step S208 that the current detector 240 is unable to perform the sensing operation of the test current ILT or the relays RL1, RL2 are unable to be turned off, and provides a warning signal. On the other hand, in response to the relays RL1, RL2 being turned off to make the current value of the test current ILT equal to 0, the controller 230 generates the timing value CV in Step S209.

In Step S210, the controller 230 determines whether the relays RL1, RL2 are aging according to the timing value CV. In one embodiment, in response to the timing value CV being greater than the set value SV, the controller 230 determines in Step S211 the aging condition of the relays RL1, RL2, and provides a warning signal. On the other hand, in response to the timing value CV being less than or equal to the set value SV, the controller 230 determines in Step S212 that the relays RL1, RL2 are not aging, and allows the charging pile 10 to perform the charging operation.

Based on the above, in the detection method S200, Steps S202 and S203 detect whether the relays RL1, RL2 are operating normally (for example, whether being turned on normally). Steps S205 to S212 then detect the aging condition of the relays RL1, RL2.

In summary, the detection device and the detection method of the disclosure generate the timing value based on the generation of the test current. The timing value is related to the time required for the relay to complete tripping. As a result, the detection device and the detection method may determine the aging condition of the relay according to the timing value.

Although the disclosure has been disclosed by the foregoing embodiments, the embodiments are not intended to limit the disclosure. Persons skilled in the art may make some modifications and changes without departing from the spirit and scope of the disclosure. Therefore, the protection scope of the disclosure should be defined by the appended claims.

What is claimed is:

1. A detection device for a charging pile, wherein the charging pile includes a first power line, a second power line, a first output terminal, a second output terminal, and a relay, the second output terminal is connected to the second power line, a first terminal of the relay is connected to the first power line, and a second terminal of the relay is connected to the first output terminal, the detection device comprising:
a virtual load circuit connected between the second output terminal and the second terminal of the relay;
a detection circuit connected to the first power line and the second power line; and
a controller connected to the relay, the virtual load circuit, and the detection circuit, the controller being configured to:
turn on the relay and control the virtual load circuit, and a virtual load path is formed between the second output terminal and the second terminal of the relay,
control the detection circuit, a test current is generated between the first power line and the second power line, and timing is begun from the generation of the test current,
turn off the relay in response to the test current, the generation of the test current is stopped, and timing is ended, and a timing value is generated, and
determine an aging condition of the relay using the timing value.

2. The detection device as claimed in claim 1, wherein the controller is configured to determine whether the relay is aging using a comparison result between the timing value and a set value.

3. The detection device as claimed in claim 2, wherein the controller is configured to determine that the relay is aging in response to the timing value being greater than the set value.

4. The detection device as claimed in claim 1, further comprising:
a first current detector connected to the controller, and configured to generate a current detection signal in response to the test current.

5. The detection device as claimed in claim 4, wherein
the controller is configured to time the generation of the test current using the current detection signal, and provide a control signal, and
the relay is configured to be turned off using the control signal.

6. The detection device as claimed in claim 5, further comprising:
a second current detector connected to the controller configured to sense the test current flowing through the first power line or the second power line, and a sensor signal is generated then provided to the controller,
wherein the controller is configured to stop timing, and the timing value is generated in response to the sensor signal indicating that a current value of the test current is equal to zero.

7. The detection device as claimed in claim 1, wherein the detection circuit comprises:
a programmable resistor circuit; and
a test switch connected in series with the programmable resistor circuit between the first power line and the second power line;
wherein the controller is configured to turn on the test switch during a period in which the virtual load path is provided, , and adjust a resistance value of the programmable resistor circuit, and a current value of the test current is reached a set current value.

8. The detection device as claimed in claim 7, further comprising:
a voltage sensor configured to sense a voltage value on the first power line, and a voltage detection signal is generated,
wherein the controller is configured to adjust the resistance value of the programmable resistor circuit using the voltage detection signal and the set current value, and the current value of the test current is reached the set current value.

9. The detection device as claimed in claim 1, wherein the virtual load circuit comprises:
a virtual load; and
a load switch connected in series with the virtual load between the second output terminal and the second terminal of the relay,
wherein the controller is configured to turn on the relay and the load switch, and the virtual load path is formed.

10. A detection method for a charging pile, wherein the charging pile includes a first power line, a second power line, a first output terminal, a second output terminal, and a relay, the second output terminal is connected to the second power line, a first terminal of the relay is connected to the first power line, and a second terminal of the relay is connected to the first output terminal, the detection method comprising:
providing a virtual load circuit and a detection circuit, wherein the virtual load circuit is connected between the second output terminal and the second terminal of the relay, and the detection circuit is connected to the first power line and the second power line;
turning on the relay and controlling the virtual load circuit, and a virtual load path being formed between the second output terminal and the second terminal of the relay;
controlling the detection circuit, a test current being generated between the first power line and the second power line, and timing being begun from the generation of the test current;
turning off the relay in response to the test current, the generation of test current being stopped, timing being ended, and a timing value being generated; and
determining an aging condition of the relay using the timing value.

11. The detection method as claimed in claim 10, wherein determining the aging condition of the relay using the timing value comprises:
determining whether the relay is aging using a comparison result between the timing value and a set value.

12. The detection method as claimed in claim 11, wherein determining whether the relay is aging using the comparison result between the timing value and the set value comprises:
determining that the relay is aging in response to the timing value being greater than the set value, and a warning signal being provided.

13. The detection method as claimed in claim 11, wherein determining whether the relay is aging using the comparison result between the timing value and the set value comprises:
determining that the relay is not aging in response to the timing value being less than or equal to the set value, and the charging pile being allowed to perform charging operation.

14. The detection method as claimed in claim 10, wherein controlling the detection circuit, the test current being generated between the first power line and the second power line, and timing being begun from the generation of the test current, comprises:
generating a current detection signal in response to the test current; and
beginning timing from the generation of the test current using the current detection signal, and providing a control signal,
wherein the relay is configured to be turned off using the control signal.

15. The detection method as claimed in claim 14, further comprising:
providing a warning signal in response to the relay being unable to be turned off using the control signal.

16. The detection method as claimed in claim 14, wherein turning off the relay in response to the test current to stop the generation of the test current, and ending timing to generate the timing value comprises:
sensing the test current flowing through the first power line or the second power line, and a sensor signal being generated;
stopping timing to generate the timing value in response to the sensor signal indicating that a current value of the test current is equal to zero.

17. The detection method as claimed in claim 10, wherein the detection circuit comprises a programmable resistor circuit and a test switch, the test switch is connected in series with the programmable resistor circuit between the first power line and the second power line, and wherein controlling the detection circuit to generate the test current between the first power line and the second power line comprises:
turning on the test switch during a period in which the virtual load path is provided, and adjusting a resistance value of the programmable resistor circuit a current value of the test current, and reach a set current value being reached.

18. The detection method as claimed in claim 17, further comprising:
sensing a voltage value on the first power line, and a voltage detection signal being generated; and
adjusting the resistance value of the programmable resistor circuit using the voltage detection signal and the set current value, and the current value of the test current being reached the set current value.

19. The detection method as claimed in claim 10, wherein the virtual load circuit comprises a virtual load and a load switch, the load switch is connected in series with the virtual load between the second output terminal and the second terminal of the relay, and wherein the step of turning on the relay and controlling the virtual load circuit, and the virtual load path being formed between the second output terminal and the second terminal of the relay comprises:
turning on the relay and the load switch, and the virtual load path being formed.

20. The detection method as claimed in claim 19, further comprising:
determining whether there is current flowing through the virtual load path; and
determining that one of the relay and the load switch is abnormal in response to no current flowing through the virtual load path, and a warning signal being provided.
